(19) United States
(12) Patent Application Publication
(10) Pub. No.: US 2006/0022210 A1
(43) Pub. Date: Feb. 2, 2006

(54) Radiation-emitting semiconductor chip with a beam shaping element and beam shaping element

(75) Inventor: Klaus Streubel, Laaber (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/171,708

(22) Filed: Jun. 30, 2005

(30) Foreign Application Priority Data
Jun. 30, 2004 (DE) 10 2004 031 732.1

(51) Int. Cl. H01L 33/00

(52) U.S. Cl. 257/98

(57) ABSTRACT

In a radiation-emitting semiconductor chip (2) with a beam shaping element, the beam shaping element is a hollow body (1) with a light exit opening (7). In a first embodiment, the semiconductor chip (2) has a light entry opening (8) opposite the light exit opening (7), the semiconductor chip (2) adjoining said light entry opening. In a second embodiment, the semiconductor chip (2) is arranged within the hollow body (1). At least a portion of the radiation (3) emitted by the semiconductor chip (2) is reflected at a wall (6) of the hollow body (1) toward the light exit opening (7).

### RELATED APPLICATION

This patent application claims the priority of German patent application 10 2004 031 732.1, the disclosure content of which is hereby incorporated by reference.

### FIELD OF THE INVENTION

The invention relates to a radiation-emitting semiconductor chip with a beam shaping element.

### BACKGROUND OF THE INVENTION

In order to improve the beam quality, in particular in order to reduce the beam divergence and/or the beam cross section, optoelectronic components with radiation-emitting semiconductor chips, for example light emitting diodes, often make use of beam shaping elements, such as lenses and optical waveguides, for example, which are arranged downstream of the semiconductor chip in the main radiation direction.

One example of a beam shaping element of this type is an optical waveguide comprising a solid plastic body having a light entry side and a light exit side. Such optical waveguides are described for example in Siemens Components 29 (1991) Issue 5, pages 193 to 196. In the case of the optical waveguides explained therein, a radiation emitted by an LED component is coupled into the optical waveguide through the light entry side, reflected at the interfaces of the optical waveguide with respect to the surrounding atmosphere, and in the further course coupled out of the optical waveguide again through the light exit side.

The radiation emitted by the semiconductor chip generally passes through an air gap from the semiconductor chip to the light entry side of the optical waveguide. However, this has the disadvantage that a portion of the radiation emitted by the semiconductor chip is reflected back at the light entry area of the concentrator and is thus lost.

In the case of an optical waveguide made of a plastic, there is the problem in connection with semiconductor chips which emit radiation or at least radiation components in the ultraviolet spectral region that the plastic degrades as a result of the UV radiation, as a result of which the long-term stability, in particular, may be impaired. This problem occurs particularly in the case of semiconductor chips which emit blue or white light since the emission spectrum thereof extends into the ultraviolet region of the spectrum.

### SUMMARY OF THE INVENTION

One object of the invention is to provide a radiation-emitting semiconductor chip with an improved beam shaping element and also such a beam shaping element which is distinguished in particular by reduced losses in the course of coupling in radiation and a comparatively high resistance toward ultraviolet radiation.

This and other objects are attained in accordance with one aspect of the invention directed to a radiation-emitting semiconductor chip with a beam shaping element. The beam shaping element comprises a hollow body with a light exit opening and a light entry opening, opposite the light exit opening. The semiconductor chip adjoins the light entry opening of the hollow body or projects through the light entry opening of the hollow body into the latter in such a way that the semiconductor chip emits electromagnetic radiation into the hollow body and at least a portion of said electromagnetic radiation is reflected at a wall of the hollow body toward the light exit opening.

Another aspect of the present invention is directed to a beam shaping element with a hollow body, which has a light exit opening. A light entry opening is provided opposite the light exit opening. Light can be coupled in through the light entry opening from a radiation-emitting semiconductor chip. A wall connects the light exit opening to the light entry opening and forms the hollow body. The hollow body is filled with a radiation-transmissive material.

By virtue of the fact that the semiconductor chip directly adjoins the light entry opening of the hollow body or is arranged within the hollow body, reflection losses when the radiation enters the beam shaping element are advantageously low. This is advantageous in particular in comparison with beam shaping elements that are separated from the semiconductor chip by an air gap.

A further advantage of the invention is that the hollow body has an opening opposite the light exit opening, so that the hollow body can either be placed with the opening onto the semiconductor chip or be slipped over the semiconductor chip. In the first-mentioned case, the opening fulfills the function of a light entry opening. The mounting and alignment of the hollow body can thereby advantageously be effected after the mounting and the contact-connection of the semiconductor chip. This is not possible for example with a prefabricated chip housing into which a semiconductor chip is subsequently inserted.

The hollow body may be filled with a potting material, for example. The potting material is preferably a UV-stable material, such as silicone, for example.

The wall of the hollow body preferably has a curvature in order to realize a desired optical functionality. In particular, the wall of the hollow body may be curved aspherically, for example parabolically, elliptically or hyperbolically.

The divergence of the radiation emitted by the semiconductor chip is advantageously reduced by the beam shaping element. An advantageous embodiment of the hollow body consists in the cross section of the hollow body tapering from the light exit opening toward the opposite opening. Furthermore, the hollow body may have an axis of symmetry parallel to a main beam direction of the radiation-emitting semiconductor chip.

The invention is particularly advantageous for radiation-emitting semiconductor chips which emit white light, blue light or ultraviolet radiation since, through the use of a hollow body as a beam shaping element, the problem of UV resistance is reduced in comparison with known beam shaping elements that contain a solid body made of plastic.

The material of the hollow body can be a material having a high reflection for the radiation emitted by the semiconductor chip. The wall of the hollow body is particularly advantageously provided with a reflection-increasing coating.

The hollow body is produced from a plastic, for example. It is particularly advantageous if the hollow body comprises a material that is deformable in such a way that the curvature of the wall is changeable or is not produced until after mounting. In this way, the desired optical function of the hollow body can still be altered or corrected after mounting. This possibility for subsequent correction of the optical properties affords a high alignment tolerance for the mounting of the semiconductor chip and of the hollow body. The outlay in respect of mounting and alignment is particularly low if the hollow body is a one-piece hollow body.

### BRIEF DESCRIPTION OF THE DRAWINGS

FIG. 1 shows a schematic illustration of a cross section through an exemplary embodiment of a radiation-emitting semiconductor chip with a beam shaping element in accordance with the first embodiment of the invention, and

FIG. 2 shows a schematic illustration of a cross section through an exemplary embodiment of a radiation-emitting semiconductor chip with a beam shaping element in accordance with the second embodiment of the invention.

FIG. 3 shows a schematic illustration of a cross section through an exemplary embodiment of a radiation-emitting semiconductor chip with a beam shaping element in accordance with the third embodiment of the invention.

### DETAILED DESCRIPTION OF THE DRAWINGS

Identical or identically acting elements are provided with the same reference symbols in the figures.

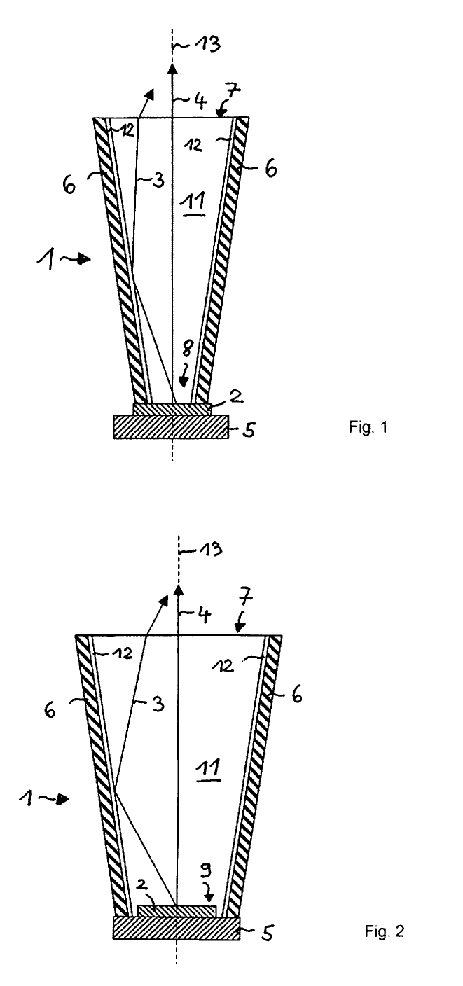

The radiation-emitting semiconductor chip 2 illustrated in FIG. 1 is provided with a beam shaping element. The beam shaping element is a hollow body 1 having a light exit opening 7 and a light entry opening 8. The hollow body 1 is placed onto the semiconductor chip 2 in such a way that the light entry opening 8 adjoins the semiconductor chip 2. The radiation 3 emitted by the semiconductor chip 2 is reflected at the wall 6 of the hollow body 1 toward the light exit area 7 of the hollow body.

The hollow body 1 may be shaped for example in such a way that the wall 6 between the light entry opening 8 and the light exit area 7, as illustrated in FIG. 1, has no curvature in the direction parallel to the main beam direction 4 of the semiconductor chip 2.

Depending on the desired function of the beam shaping element, however, the wall 6 may also have a curvature, in particular an aspherical curvature, in the direction parallel to the main beam direction 4 of the semiconductor chip 2. By way of example, a parabolic, elliptical or hyperbolic curvature may be provided in order, for example, to reduce the beam divergence of the radiation 3 emitted by the semiconductor chip 2. FIG. 3 shows a beam shaping element with such a curved wall 6.

The hollow body 1 is preferably produced from a deformable material, for example a plastic. In this case, the curvature of the wall 6 can still be produced and/or altered after the mounting of the hollow body onto the semiconductor chip 2.

The hollow body 1 is rotationally symmetrical about an axis 13 of symmetry running parallel to the main beam direction 4. Since the cross section of the hollow body 1 in the embodiment shown tapers from the light exit area 7 toward the light entry opening 8, the hollow body 1 has the form of a truncated cone.

The wall 6 of the hollow body 1 is preferably provided with a reflection-increasing coating 12, containing a metal for example. Said coating 12 may be applied on the interior side of the wall 6. If the wall of the hollow body is transparent for the radiation that is emitted by the semiconductor chip, the reflection-increasing coating can also be applied to the exterior side of the hollow body. A reason to do so may be that it is sometimes less difficult to apply a coating on the exterior surface than on the interior surface of the hollow body. A reflection-increasing coating 12 is advantageous particularly when the hollow body 1 comprises a plastic and the semiconductor chip 2 emits radiation whose spectrum at least partly extends right into the ultraviolet spectral region, as is the case for example with light emitting diodes that emit blue or white light. In this case, the reflection-increasing coating 12 not only increases the reflection of the hollow body 1 made of plastic but also protects the plastic against the ultraviolet radiation that might damage the plastic in particular after a relatively long operational time.

The hollow body 1 is preferably filled with a potting composition 11 in order for example to protect the semiconductor chip 2 against environmental influences. Furthermore, the potting composition may also contain luminescence conversion particles in order for example to generate white light with a semiconductor chip 2 emitting blue or ultraviolet radiation. For the abovementioned semiconductor chips that at least partly emit in the ultraviolet spectral region, silicone, in particular, is suitable as a potting material since this is distinguished by a high UV resistance.

The semiconductor chip 2 is mounted for example onto a chip carrier 5, in particular onto a leadframe or a printed circuit board. The chip carrier 5 may contain connection regions for the electrical contact-connection of the semiconductor chip 2. Furthermore, the chip carrier 5 may also comprise a heat sink.

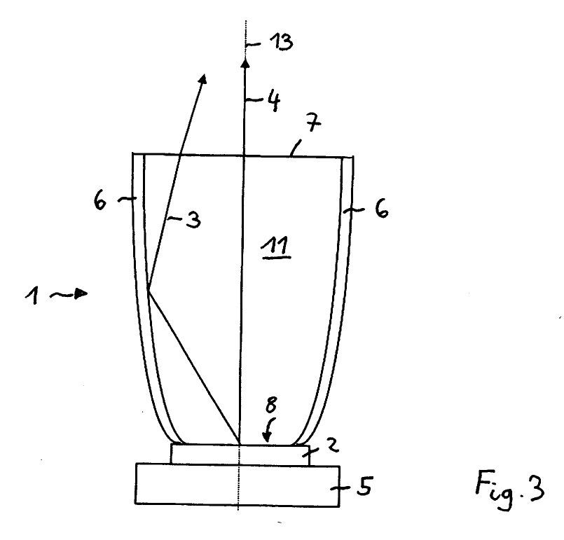

The exemplary embodiment—illustrated in FIG. 2—of a radiation-emitting semiconductor chip 2 with a beam shaping element in accordance with the second embodiment of the invention differs from the exemplary embodiment illustrated in FIG. 1 essentially by the fact that the hollow body 1 is not placed onto the semiconductor chip 2, rather the semiconductor chip 2 is arranged completely within the hollow body 1. This may be realized for example by placing the hollow body 1 with an opening 9 opposite the light exit opening 7 onto the chip carrier 5 in such a way that the semiconductor chip 2 mounted onto the chip carrier 5 is completely enclosed by the hollow body 1.

As an alternative, the semiconductor chip 2 may also be positioned in the hollow body 1 and be potted with the potting composition 11, so that after the curing of the potting composition 11, the semiconductor chip 2 is fixed even without a chip carrier in the hollow body 1.

The second embodiment of the invention, too, has the advantage that the radiation 3 emitted by the semiconductor chip 2 directly enters the hollow body 1 acting as a beam shaping element without passing through an air gap beforehand, whereby reflection losses are avoided.

The exemplary embodiments of a hollow body 1 that are illustrated in FIGS. 1 and 2 are in each case rotationally symmetrical about an axis 13 of symmetry running parallel to the main beam direction 4 of the semiconductor chips 2. Depending on the desired optical function of the beam shaping element, other embodiments of the hollow body 1 are also conceivable, of course, within the scope of the invention.

Furthermore, the hollow body 1 may also be succeeded by one or more optical elements, for example a lens or lens combination.

In the exemplary embodiments, the hollow bodies 1 are preferably produced from a deformable material, for example a plastic. In this case, the curvature of the wall 6 can still be produced and/or altered after the mounting of the hollow body 1 onto the semiconductor chip 2 or after the positioning of the semiconductor chip 2 in the hollow body 1. In particular, a curvature of the wall 6 that is already present before mounting may be corrected after mounting in order to obtain the desired optical properties.

With the arrangement of the present invention, at least a portion of the electromagnetic radiation is subjected to total reflection at the wall 6 of the hollow body toward the light exit opening 7. A total reflection at the wall of the hollow body can take place when a) the refractive index inside the hollow body is larger than the refractive index of the wall, e.g., in case that the hollow body is filled with a transparent material like a silicone resin, and b) the angle of incidence of the reflected radiation is larger than a critical angle that depends on the refractive indices of the transparent material and the wall. The advantage of a “total reflection” at the wall is that the radiation is completely reflected toward the light entrance opening and cannot escape from the hollow body through the sidewalls.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

I claim:

1. A radiation-emitting semiconductor chip (2) with a beam shaping element, wherein
the beam shaping element comprises a hollow body (1) with a light exit opening (7) and a light entry opening (8), opposite the light exit opening (7),
the semiconductor chip (2) adjoins the light entry opening (8) of the hollow body (1) or projects through the light entry opening (8) of the hollow body (1) into the latter in such a way that the semiconductor chip (2) emits electromagnetic radiation into the hollow body (1) and at least a portion of said electromagnetic radiation (3) is reflected at a wall (6) of the hollow body (1) toward the light exit opening (7).

2. The radiation-emitting semiconductor chip (2) as claimed in claim 1, wherein at least a portion of the electromagnetic radiation (3) is subjected to total reflection at the wall (6) of the hollow body (1) toward the light exit opening (7).

3. The radiation-emitting semiconductor chip (2) as claimed in claim 1, wherein the hollow body (1) is filled with a radiation-transmissive material (11).

4. The radiation-emitting semiconductor chip (2) as claimed in claim 3, wherein the radiation-transmissive material (11) contains silicone, and is preferably a silicone resin.

5. The radiation-emitting semiconductor chip (2) as claimed in claim 1, wherein the wall (6) of the hollow body (1) has an aspherical curvature.

6. The radiation-emitting semiconductor chip (2) as claimed in claim 5, wherein the wall (6) of the hollow body (1) is curved parabolically, elliptically or hyperbolically.

7. The radiation-emitting semiconductor chip (2) as claimed in claim 1, wherein the beam shaping element reduces the divergence of the radiation (3) emitted into the hollow body (1) by the semiconductor chip (2).

8. The radiation-emitting semiconductor chip (2) as claimed in claim 1, wherein the cross section of the hollow body (1) tapers from the light exit opening (7) toward the light entry opening (8, 9).

9. The radiation-emitting semiconductor chip (2) as claimed in claim 1, wherein the hollow body (1) has an axis (13) of symmetry parallel to a main beam direction (4) of the radiation-emitting semiconductor chip (2).

10. The radiation-emitting semiconductor chip (2) as claimed in claim 1, wherein the semiconductor chip (2) emits ultraviolet radiation.

11. The radiation-emitting semiconductor chip (2) as claimed in claim 1, wherein the semiconductor chip (2) emits blue or white light.

12. The radiation-emitting semiconductor chip (2) as claimed in claim 1, wherein the wall (6) of the hollow body (1) is provided with a reflection-increasing coating (12).

13. The radiation-emitting semiconductor chip (2) as claimed in one claim 1, wherein the hollow body (1) is produced from a plastics material.

14. The radiation-emitting semiconductor chip (2) as claimed in claim 1, wherein the hollow body (1) comprises a material that is deformable in such a way that the curvature of the wall (6) is changeable.

15. A beam shaping element with a hollow body (1), which has a light exit opening (7), a light entry opening (8) opposite the light exit opening (7), through which light entry opening light from a radiation-emitting semiconductor chip (2) can be coupled in, and a wall (6) that connects the light exit opening (7) to the light entry opening (8) and forms the hollow body (1), the hollow body (1) being filled with a radiation-transmissive material (11).

16. The beam shaping element as claimed in claim 15, in which the radiation-transmissive material (11) contains silicone, and is preferably a silicone resin.

17. The beam shaping element as claimed in claim 15, in which the wall (6) of the hollow body (1) has an aspherical curvature.

18. The beam shaping element as claimed in claim 17, in which the wall (6) of the hollow body (1) is curved parabolically, elliptically or hyperbolically.

19. The beam shaping element as claimed in claim 15, in which the beam shaping element reduces the divergence of a radiation (3) emitted into the hollow body (1) by a semiconductor chip (2).

20. The beam shaping element as claimed in claim 15, in which the cross section of the hollow body (1) tapers from the light exit opening (7) toward the light entry opening (8, 9).

21. The beam shaping element as claimed in claim 15, in which the wall (6) is provided with a reflection-increasing coating (12).

22. The beam shaping element as claimed in claim 15, in which the hollow body (1) is produced from a plastics material.

23. The beam shaping element as claimed in claim 15, in which the hollow body (1) comprises a material that is deformable in such a way that the curvature of the wall (6) is changeable.
